(19) United States
(12) Patent Application Publication
(10) Pub. No.: US 2025/0140682 A1
(43) Pub. Date: May 1, 2025

(54) STORAGE DEVICE INCLUDING CAPACITOR REMOVABLY MOUNTED ON CASE

(71) Applicant: Samsung Electronics Co., Ltd., Suwon-si (KR)

(72) Inventor: Jiyong KIM, Suwon-si (KR)

(73) Assignee: Samsung Electronics Co., Ltd., Suwon-si (KR)

(21) Appl. No.: 18/791,593

(22) Filed: Aug. 1, 2024

(30) Foreign Application Priority Data
Oct. 30, 2023 (KR) 10-2023-0147065

(51) Int. Cl. H01L 23/522; H01L 23/13; H01L 23/367; H01L 25/11; H01L 25/16

(52) U.S. Cl. CPC H01L 23/5223; H01L 23/13; H01L 23/3672; H01L 25/115; H01L 25/165

(57) ABSTRACT

A storage device may include a substrate; a semiconductor chip on the substrate; a case including a plurality of heat dissipation fins, a cavity, and a capacitor module configured to be electrically connected to the substrate, the heat dissipation fins being arranged in a first direction and spaced apart from each other in a second direction that is perpendicular to the first direction, and an upper cover on the case. The capacitor module may include a capacitor in the cavity and the capacitor may be configured to supply power to the substrate.

### CROSS-REFERENCE TO RELATED APPLICATION

This application is based on and claims priority under 35 U.S.C. § 119 to Korean Patent Application No. 10-2023-0147065, filed on Oct. 30, 2023 in the Korean Intellectual Property Office, the disclosure of which is incorporated by reference herein in its entirety.

### BACKGROUND

Inventive concepts relate to a storage device, and more particularly, to a storage device including a removable capacitor module.

In general, storage devices including memory devices and a memory controller operate with power provided from the outside. A sudden-power off (SPO) situation, in which power is suddenly cut off while storage devices are operating, may occur. At this time, a memory controller stores data by using volatile memory, and accordingly, the data stored in the volatile memory may be lost or the current operation (e.g., an erase operation, a write operation, or the like) of a memory device may not be completed. In this case, storage devices complete the current operation and perform data backup, by using an auxiliary power supply including a capacitor.

### SUMMARY

Inventive concept provide a storage device capable of securing space on a substrate thereof by arranging a capacitor module in a case of the storage device, wherein the capacitor module may be obtained by modularizing a capacitor on the substrate of the storage device. A semiconductor chip may be arranged in the secured space, and therefore, the capacity of the storage device may be increased.

Inventive concepts also provide a storage device capable of reducing manufacturing costs by adjusting the number of capacitors included in the storage device by using a removable capacitor module.

Aspects of inventive concepts are not limited to those mentioned above, and aspects of inventive concepts that have not been mentioned will be clearly understood by one of skill in the art from the description below.

According to an embodiment of inventive concepts, a storage device may include a substrate; a semiconductor chip on the substrate; a case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction; and an upper cover on the case. The capacitor module may include a capacitor in the cavity and the capacitor may be configured to supply power to the substrate.

According to an embodiment of inventive concepts, a storage device may include a substrate; a first semiconductor chip on a top surface of the substrate; a second semiconductor chip on a bottom surface of the substrate; a case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction; and an upper cover on the case. The capacitor module may include a capacitor in the cavity and the capacitor may be configured to supply power to the substrate.

According to an embodiment of inventive concepts, a storage device may include a substrate; a semiconductor chip on the substrate; an upper case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction; a lower case configured to be coupled to the upper case; and an upper cover on the upper case. The substrate may be in the lower case. The capacitor module may include a capacitor in the cavity. The upper case may be configured to be coupled to the lower case and allow power to be supplied to the substrate.

### BRIEF DESCRIPTION OF THE DRAWINGS

Embodiments will be more clearly understood from the following detailed description taken in conjunction with the accompanying drawings in which:

FIGS. 1 to 3 are diagrams of a storage device according to an embodiment;

FIG. 4 is a cross-sectional view of a storage device according to an embodiment;

FIG. 5 is a cross-sectional view of a storage device according to an embodiment;

FIG. 6 is a diagram illustrating a capacitor module according to an embodiment;

FIG. 7 is a cross-sectional view of a storage device according to an embodiment;

FIG. 8 is a cross-sectional view of a storage device according to an embodiment;

FIG. 9 is a cross-sectional view of a storage device according to an embodiment;

FIG. 10 is a diagram of a system including a storage device, according to an embodiment; and

FIG. 11 is a block diagram of an example of applying a storage device to a solid state drive (SSD) system, according to embodiments.

### DETAILED DESCRIPTION OF THE EMBODIMENTS

The terminology used herein is for the purpose of describing particular embodiments only and is not intended to be limiting of example embodiments. As used herein, the singular forms “a,” “an” and “the” are intended to include the plural forms as well, unless the context clearly indicates otherwise.

Hereinafter, embodiments will be described in detail with reference to the accompanying drawings. In the drawings, like reference characters denote like elements and redundant descriptions thereof will be omitted.

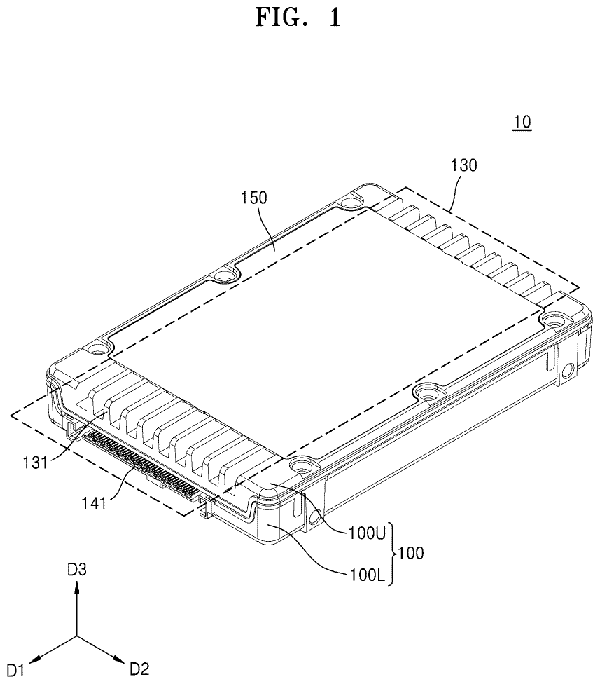

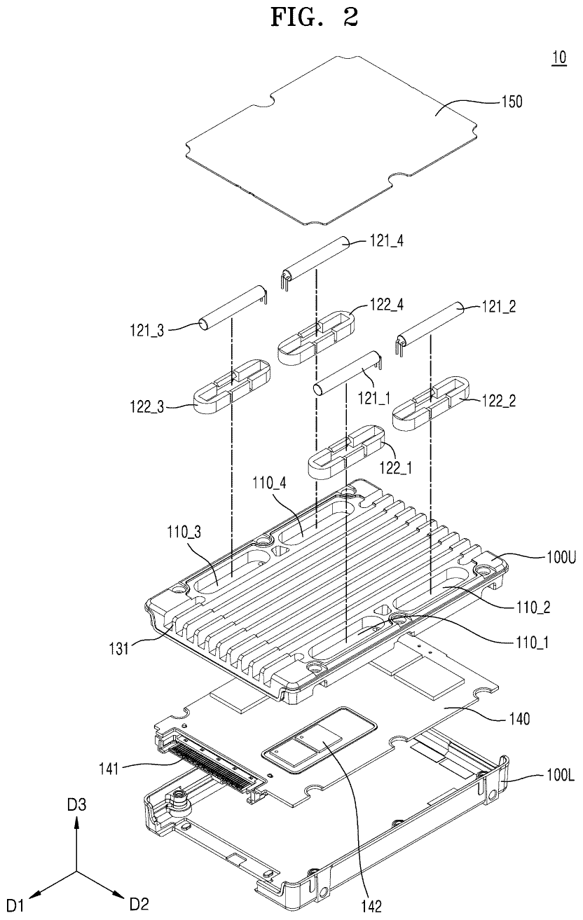

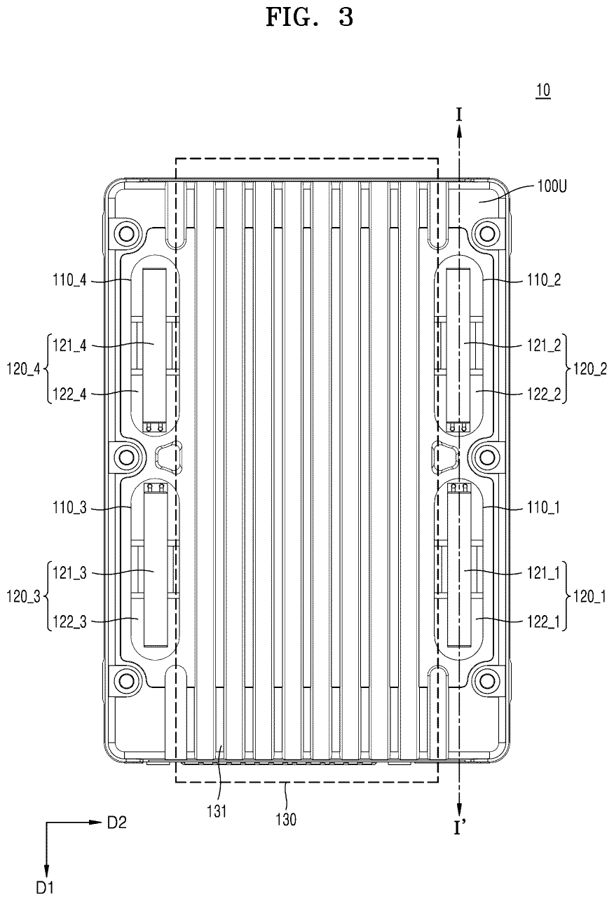

FIGS. 1 to 3 are diagrams of a storage device according to an embodiment. In detail, FIG. 1 is a perspective view of a storage device 10 according to an embodiment. FIG. 2 is an exploded perspective view of the storage device 10 according to an embodiment. FIG. 3 is a plan view of the storage device 10, from which an upper cover 150 is removed, according to an embodiment.

Referring to FIGS. 1 to 3, the storage device 10 may include a case 100, a substrate 140, and the upper cover 150.

The storage device 10 may operate with power provided from the outside. Herein, a mode in which the storage device 10 operates with power provided from the outside may be referred to as a normal power mode. A sudden-power off (SPO) situation, in which power is suddenly cut off while the storage device 10 is operating, may occur. At this time, data stored in the storage device 10 may be lost or the current operation (e.g., an erase operation, a write operation, or the like) of the storage device 10 may not be completed. In this case, the storage device 10 may perform the operation using an auxiliary power supply. The storage device 10 may include a power loss protection (PLP) integrated circuit (IC). Herein, a mode in which the storage device 10 operates with power from an auxiliary power supply may be referred to as an auxiliary power mode. The auxiliary power supply may refer to first to fourth capacitor modules 120_1 to 120_4.

The case 100 may include an upper case 100U and a lower case 100L. The upper case 100U may be removably coupled to the lower case 100L. The case 100 may include a material having high thermal conductivity to be suitable for discharging heat, which is generated from a component, e.g., a semiconductor chip 142, in the case 100, to the outside of the case 100. The case 100 may be constituted of a single material or a combination of different materials. The case 100 may include a metal, a carbon-based material, a polymer, or a combination thereof. For example, the case 100 may include copper (Cu), aluminum (Al), zinc (Zn), tin (Sn), stainless steel, or a clad metal including the same. For example, the case 100 may include graphite, graphene, carbon fiber, or a carbon nanotube composite. For example, the case 100 may include epoxy resin, polymethylmethacrylate (PMMA), polycarbonate (PC), polyethylene (PE), or polypropylene (PP).

The upper case 100U may include first to fourth cavities 110_1 to 110_4, the first to fourth capacitor modules 120_1 to 120_4, and a heat dissipation structure 130.

In an embodiment, the upper case 100U may include at least one cavity. Although four cavities (e.g., 110_1 to 110_4) are illustrated in FIGS. 2 and 3, less or more cavities may be included in the upper case 100U. The upper case 100U may also include at least one capacitor module. Although four capacitor modules (e.g., 120_1 to 120_4) are illustrated in FIGS. 2 and 3, less or more capacitor modules may be included in the upper case 100U.

The first to fourth cavities 110_1 to 110_4 may be formed in the upper case 100U. The depth of the first to fourth cavities 110_1 to 110_4, e.g., the length of the first to fourth cavities 110_1 to 110_4 in a third direction D3 that is the vertical direction of the case 100, may be less than the length of the upper case 100U in the third direction D3.

The first to fourth capacitor modules 120_1 to 120_4 may be electrically connected to the substrate 140. In detail, a capacitor included in each capacitor module may be electrically connected to the substrate 140 via a lead of the capacitor, which contacts the substrate 140 through a hole formed in the upper case 100U.

In an embodiment, the storage device 10 may operate in the auxiliary power mode when an SPO occurs. In other words, the storage device 10 may complete a current operation using energy stored in the first to fourth capacitor modules 120_1 to 120_4, thereby limiting and/or preventing data to be stored in the storage device 10 from being lost.

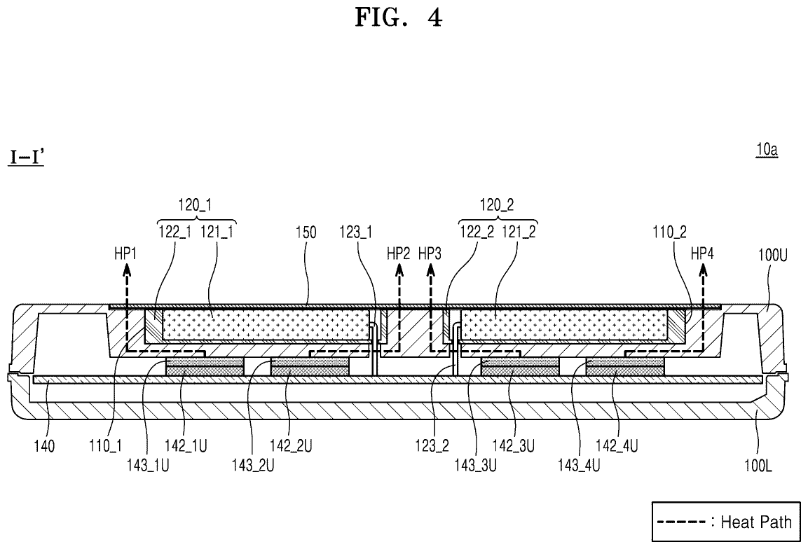

The first capacitor module 120_1 may include a first capacitor 121_1 and a first housing 122_1. The first capacitor 121_1 may store energy, which is required to operate the storage device 10 in an SPO situation. The first housing 122_1 may include a latch and may fix the first capacitor 121_1 via the latch. The configuration of each of the second to fourth capacitor modules 120_2 to 120_4 may be the same as the configuration of the first capacitor module 120_1, and thus, redundant descriptions thereof are omitted. Each of the first to fourth capacitor modules 120_1 to 120_4 may include various components, such as a fixing pad, an adhesive member, and a pogo pin, in addition to a housing. The embodiments thereof are described with reference to FIGS. 4 to 9 below.

In an embodiment, the first to fourth capacitor modules 120_1 to 120_4 may be configured to be attachable to and detachable from the upper case 100U. For example, energy required by the storage device 10 in an SPO situation may be sufficiently provided by a single capacitor module. In this case, the manufacturer of the storage device 10 may release the storage device 10 after detaching the second to fourth capacitor modules 120_2 to 120_4, excluding the first capacitor module 120_1, during the production process of the storage device 10. As described above, the manufacturing cost of the storage device 10 may be reduced by adjusting the number of capacitor modules required in the storage device 10.

The heat dissipation structure 130 may include a plurality of heat dissipation fins 131. Heat originated from a plurality of semiconductor chips 142 may be emitted to the outside through the heat dissipation structure 130. The heat originated from the semiconductor chips 142 may be emitted to the outside through a heat path formed in the storage device 10.

Each of the heat dissipation fins 131 may extend in a first direction D1. The heat dissipation fins 131 may be apart from each other in a second direction D2 that is perpendicular to the first direction D1.

In an embodiment, heat generated in each semiconductor chip 142 may be emitted to the outside through a heat path, which leads from the semiconductor chip 142 to the bottom surface of the upper case 100U, to the heat dissipation fins 131, and to the upper cover 150. In an embodiment, a thermal interface material (TIM) may be arranged on the top surface of each of the semiconductor chips 142. For example, the TIM may include thermal paste, thermal adhesive, a gap filler, or a thermal conductive pad.

The substrate 140 may be arranged inside the case 100. In an embodiment, the substrate 140 may be arranged in the lower case 100L. The substrate 140 may include a printed circuit board (PCB). For example, the substrate 140 may include a double-sided PCB or a multi-layer PCB. For example, the substrate 140 may include a base layer and wiring layers respectively formed in the top and bottom surfaces of the base layer. The base layer may include at least one material selected from the group consisting of phenol resin, epoxy resin, and polyimide. The wiring layers may include a conductive material, e.g., aluminum (Al), copper (Cu), nickel (Ni), or tungsten (W). The semiconductor chips 142 and electronic components, which are mounted on the substrate 140, may be electrically connected to each other through wiring layers of the substrate 140. At least one of the semiconductor chips 142 may include a controller chip and a memory semiconductor chip. Each of the semiconductor chips 142 may be referred to as a semiconductor package.

The controller chip may control the memory semiconductor chip. A control circuit unit may be embedded in the controller chip. The control circuit unit of the controller chip may control access to data stored in the memory semiconductor chip. The control circuit unit of the controller chip may control a write or read operation of flash memory or the like according to a control command of an external host. The control circuit unit of the controller chip may be configured as a separate control semiconductor chip like an application specific IC (ASIC). For example, the control circuit unit of the controller chip may be configured to be automatically operated by the operating system of an external host when the storage device 10 is connected to the external host. The control circuit unit of the controller chip may provide a standard protocol, such as parallel advanced technology attachment (PATA), serial advanced technology attachment (SATA), a small computer system interface (SCSI) standard, or peripheral component interconnect express (PCIe). The control circuit unit of the controller chip may also execute wear leveling, garbage collection, bad block management, and error correction code for the driving of a non-volatile memory device. In this case, the control circuit unit of the controller chip may include a script for automatic execution and an application program that may be executed by the external host.

The memory semiconductor chip may include a non-volatile memory device. For example, the non-volatile memory device may include flash memory, phase-change random access memory (PRAM), resistive RAM (RRAM), ferroelectric RAM (FeRAM), or magnetic RAM (MRAM) but is not limited thereto. For example, the flash memory may include NAND flash memory. For example, the flash memory may include vertical NAND (V-NAND) flash memory. The non-volatile memory device may be constituted of a single semiconductor die or a stack of a plurality of semiconductor dies.

The memory semiconductor chip may include a volatile memory device. For example, the volatile memory device may include dynamic RAM (DRAM) or static RAM (SRAM) but is not limited thereto. The volatile memory device may provide the function of a cache, which stores data that is frequently used when an external host accesses the storage device 10, such that access time and data transfer performance may be scaled to the process performance of the external host.

Although not specifically shown, a resistor, an inductor, a switch, a temperature sensor, a direct current (DC)-DC converter, an active element, and/or a passive element may be further mounted on the substrate 140.

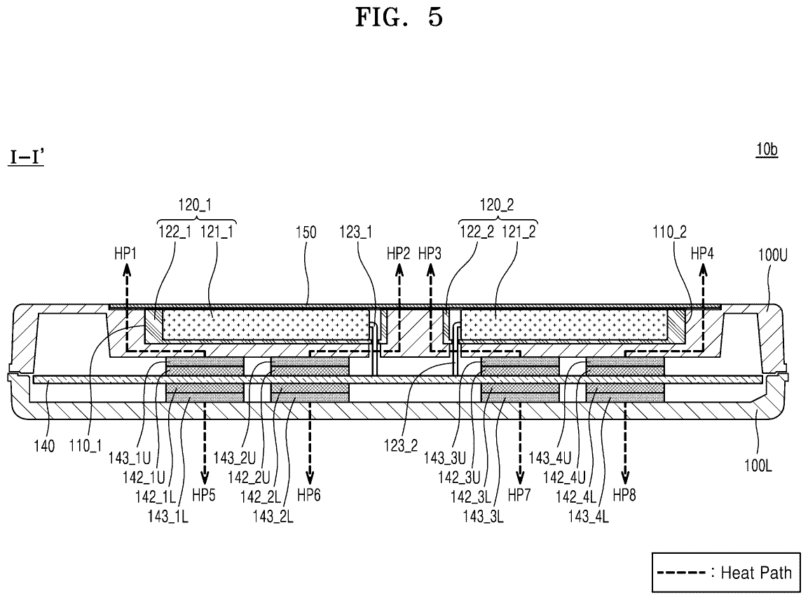

In an embodiment, the semiconductor chips 142 may be mounted on the top surface of the substrate 140. In an embodiment, semiconductor chips may also be mounted on the bottom surface of the substrate 140. This is described in detail with reference to FIG. 5 below.

The substrate 140 may include an external connector 141. The external connector 141 may be exposed to the outside by a groove formed in the case 100. The external connector 141 may be inserted into a socket of an external device and configured to electrically connect the storage device 10 to the external device. Through the external connector 141, the storage device 10 may exchange electrical signals with the external device and receive power, which is necessary for the operation of the storage device 10, from the external device.

The upper cover 150 may be coupled to the upper case 100U. In detail, the upper cover 150 may be arranged on the top surface of the upper case 100U such that first to fourth capacitors 121_1 to 121_4 are not exposed to the outside of the case 100. The upper cover 150 may overlap the heat dissipation fins 131 and the first to fourth capacitor modules 120_1 to 120_4 in the third direction D3.

According to an embodiment, the storage device 10 may operate with auxiliary power when an SPO occurs. At this time, the auxiliary power may be provided by the first to fourth capacitor modules 120_1 to 120_4 arranged in the case 100. In the storage device 10 according to an embodiment, a space for the semiconductor chips 142 may be sufficiently secured on the substrate 140 because the first to fourth capacitor modules 120_1 to 120_4 are arranged in the case 100. Because many semiconductor chips 142 may be arranged on the substrate 140 of the storage device 10 due to the sufficiently secured space on the substrate 140, the capacity of the storage device 10 may be increased.

FIG. 4 is a cross-sectional view of a storage device 10a according to an embodiment. In detail, FIG. 4 corresponds to a cross-section of the storage device 10 taken along line I-I′ in FIG. 3. FIG. 4 may be described with reference to FIGS. 1 to 3, and redundant descriptions thereof are omitted.

Referring to FIG. 4, the storage device 10a may correspond to the storage device 10 of FIGS. 1 to 3.

The storage device 10a may include the case 100, the substrate 140, and the upper cover 150.

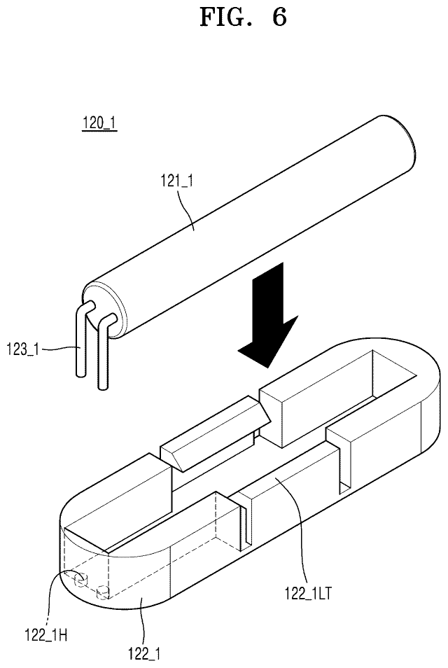

The first capacitor module 120_1 may include the first capacitor 121_1 and the first housing 122_1. The first capacitor 121_1 may be fixed to the first cavity 110_1 through the first housing 122_1. The first capacitor 121_1 may be electrically connected to the substrate 140 through a lead 123_1. The lead 123_1 may penetrate the upper case 100U through a hole, which is formed in the upper case 100U, and may be in contact with the substrate 140. The second capacitor module 120_2 may include a second capacitor 121_2 and a second housing 122_2. The second capacitor 121_2 may be fixed to the second cavity 110_2 through the second housing 122_2. The second capacitor 121_2 may be electrically connected to the substrate 140 through a lead 123_2. The lead 123_2 may penetrate the upper case 100U through a hole, which is formed in the upper case 100U, and may be in contact with the substrate 140. A housing is described in detail with reference to FIG. 6.

First semiconductor chips 142_1U to 142_4U may be mounted on the substrate 140. TIMs 143_1U to 143_4U may be respectively arranged between the first semiconductor chips 142_1U to 142_4U and the upper case 100U. Herein, a semiconductor chip on the top surface of the substrate 140 may be referred to as a first semiconductor chip and a semiconductor chip on the bottom surface of the substrate 140 may be referred to as a second semiconductor chip.

In an embodiment, the TIM 143_1U may be between the first semiconductor chip 142_1U and the upper case 100U. The TIM 143_1U may thermally connect the first semiconductor chip 142_1U to the upper case 100U. The heat dissipation fins 131 of the upper case 100U may thermally connect the upper case 100U to the upper cover 150. Accordingly, heat generated in the first semiconductor chip 142_1U may be discharged through a first heat path HP1 formed between the first semiconductor chip 142_1U and the upper cover 150. In detail, heat generated in the first semiconductor chip 142_1U may be transferred to the upper case 100U through the TIM 143_1U and then discharged to the outside through the heat dissipation fins 131 and the upper cover 150.

In an embodiment, the TIM 143_2U may be between the first semiconductor chip 142_2U and the upper case 100U. The TIM 143_2U may thermally connect the first semiconductor chip 142_2U to the upper case 100U. The heat dissipation fins 131 of the upper case 100U may thermally connect the upper case 100U to the upper cover 150. Accordingly, heat generated in the first semiconductor chip 142_2U may be discharged through a second heat path HP2 formed between the first semiconductor chip 142_2U and the upper cover 150. In detail, heat generated in the first semiconductor chip 142_2U may be transferred to the upper case 100U through the TIM 143_2U and then discharged to the outside through the heat dissipation fins 131 and the upper cover 150.

In an embodiment, the TIM 143_3U may be between the first semiconductor chip 142_3U and the upper case 100U. The TIM 143_3U may thermally connect the first semiconductor chip 142_3U to the upper case 100U. The heat dissipation fins 131 of the upper case 100U may thermally connect the upper case 100U to the upper cover 150. Accordingly, heat generated in the first semiconductor chip 142_3U may be discharged through a third heat path HP3 formed between the first semiconductor chip 142_3U and the upper cover 150. In detail, heat generated in the first semiconductor chip 142_3U may be transferred to the upper case 100U through the TIM 143_3U and then discharged to the outside through the heat dissipation fins 131 and the upper cover 150.

In an embodiment, the TIM 143_4U may be between the first semiconductor chip 142_4U and the upper case 100U. The TIM 143_4U may thermally connect the first semiconductor chip 142_4U to the upper case 100U. The heat dissipation fins 131 of the upper case 100U may thermally connect the upper case 100U to the upper cover 150. Accordingly, heat generated in the first semiconductor chip 142_4U may be discharged through a fourth heat path HP4 formed between the first semiconductor chip 142_4U and the upper cover 150. In detail, heat generated in the first semiconductor chip 142_4U may be transferred to the upper case 100U through the TIM 143_4U and then discharged to the outside through the heat dissipation fins 131 and the upper cover 150.

FIG. 5 is a cross-sectional view of a storage device 10b according to an embodiment. In detail, FIG. 5 corresponds to a cross-section of the storage device 10 taken along line I-I′ in FIG. 3. FIG. 5 may be described with reference to FIGS. 1 to 4, and redundant descriptions thereof are omitted.

Referring to FIG. 5, the storage device 10b may correspond to the storage device 10 of FIGS. 1 to 3. The storage device 10b of FIG. 5 may be obtained by additionally arranging second semiconductor chips 142_1L to 142_4L on the bottom surface of the substrate 140 of the storage device 10a of FIG. 4. Accordingly, FIG. 5 is described, focusing on the differences from FIG. 4.

The first semiconductor chips 142_1U to 142_4U may be mounted on the top surface of the substrate 140. The TIMs 143_1U to 143_4U may be respectively arranged between the first semiconductor chips 142_1U to 142_4U and the upper case 100U. Second semiconductor chips 142_1L to 142_4L may be mounted on the bottom surface of the substrate 140. TIMs 143_1L to 143_4L may be respectively arranged between the second semiconductor chips 142_1L to 142_4L and the lower case 100L.

In an embodiment, the TIM 143_1L may be between the second semiconductor chip 142_1L and the lower case 100L. The TIM 143_1L may thermally connect the second semiconductor chip 142_1L to the lower case 100L. Accordingly, heat generated in the second semiconductor chip 142_1L may be discharged through a fifth heat path HP5 formed between the second semiconductor chip 142_1L and the lower case 100L. In detail, heat generated in the second semiconductor chip 142_1L may be transferred to the lower case 100L through the TIM 143_1L and then discharged to the outside.

In an embodiment, the TIM 143_2L may be between the second semiconductor chip 142_2L and the lower case 100L. The TIM 143_2L may thermally connect the second semiconductor chip 142_2L to the lower case 100L. Accordingly, heat generated in the second semiconductor chip 142_2L may be discharged through a sixth heat path HP6 formed between the second semiconductor chip 142_2L and the lower case 100L. In detail, heat generated in the second semiconductor chip 142_2L may be transferred to the lower case 100L through the TIM 143_2L and then discharged to the outside.

In an embodiment, the TIM 143_3L may be between the second semiconductor chip 142_3L and the lower case 100L. The TIM 143_3L may thermally connect the second semiconductor chip 142_3L to the lower case 100L. Accordingly, heat generated in the second semiconductor chip 142_3L may be discharged through a seventh heat path HP7 formed between the second semiconductor chip 142_3L and the lower case 100L. In detail, heat generated in the second semiconductor chip 142_3L may be transferred to the lower case 100L through the TIM 143_3L and then discharged to the outside.

In an embodiment, the TIM 143_4L may be between the second semiconductor chip 142_4L and the lower case 100L. The TIM 143_4L may thermally connect the second semiconductor chip 142_4L to the lower case 100L. Accordingly, heat generated in the second semiconductor chip 142_4L may be discharged through an eighth heat path HP8 formed between the second semiconductor chip 142_4L and the lower case 100L. In detail, heat generated in the second semiconductor chip 142_4L may be transferred to the lower case 100L through the TIM 143_4L and then discharged to the outside.

FIG. 6 is a diagram illustrating a capacitor module according to an embodiment. In detail, the first capacitor module 120_1 of FIG. 6 may correspond to the first capacitor module 120_1 in FIGS. 4 and 5. FIG. 6 may be described with reference to FIGS. 1 to 3, and redundant descriptions thereof are omitted.

Referring to FIG. 6, the first capacitor module 120_1 may include the first capacitor 121_1 and the first housing 122_1.

The first capacitor 121_1 may be coupled to the first housing 122_1. In detail, the first capacitor 121_1 may be fixed to the first housing 122_1 by a first latch 122_1LT of the first housing 122_1.

In an embodiment, when it is necessary to adjust the number of capacitors in the storage device 10, the first capacitor module 120_1 may be removed from the upper case 100U. In an embodiment, the number of capacitors of the storage device 10 may be adjusted by removing only the first capacitor 121_1 from the first housing 122_1 of the of the first capacitor module 120_1 while leaving the first housing 122_1 in the upper case 100U.

At least one hole 122_1H may be formed in the first housing 122_1. The lead 123_1 of the first capacitor 121_1 may penetrate the first housing 122_1 through the hole 122_1H of the first housing 122_1.

Each of the second to fourth capacitor modules 120_2 to 120_4 may have a similar configuration (or same configuration) to the first capacitor module 120_1, and thus, redundant descriptions thereof are omitted.

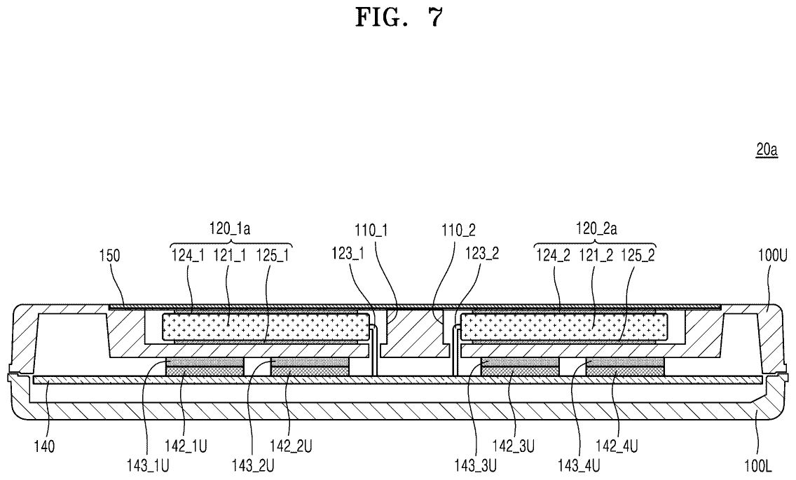

FIG. 7 is a cross-sectional view of a storage device 20a according to an embodiment. FIG. 7 may be described with reference to FIGS. 1 to 4, and redundant descriptions thereof are omitted.

Referring to FIG. 7, the storage device 20a may correspond to the storage device 10a of FIG. 4. The storage device 20a of FIG. 7 may be different from the storage device 10a of FIG. 4 in that a capacitor is fixed to a cavity by a fixing pad. Here, the fixing pad may include a silicon pad, a polyurethane pad, a thermal conductive pad, a foam pad, a rubber pad, or a combination of two or more of these but is not limited thereto. The fixing pad may include any material that is capable of fixing a capacitor to the case 100. In some embodiments, the fixing pad may be referred to as a cushion pad.

A first capacitor module 120_1a may include the first capacitor 121_1, a first upper fixing pad 124_1, and a first lower fixing pad 125_1. The first capacitor 121_1 may be electrically connected to the substrate 140 through the lead 123_1. The lead 123_1 may penetrate the upper case 100U through a hole, which is formed in the upper case 100U, and may be in contact with the substrate 140.

In an embodiment, the first capacitor 121_1 may be fixed to the first cavity 110_1 by the first upper fixing pad 124_1 and the first lower fixing pad 125_1. In detail, the first upper fixing pad 124_1 may be arranged between the upper cover 150 and the first capacitor 121_1 and may thus fix the first capacitor 121_1 to the first cavity 110_1. The first lower fixing pad 125_1 may be arranged between the upper case 100U and the first capacitor 121_1 and may thus fix the first capacitor 121_1 to the first cavity 110_1.

A second capacitor module 120_2a may include the second capacitor 121_2, a second upper fixing pad 124_2, and a second lower fixing pad 125_2. The second capacitor 121_2 may be electrically connected to the substrate 140 through the lead 123_2. The lead 123_2 may penetrate the upper case 100U through a hole, which is formed in the upper case 100U, and may be in contact with the substrate 140.

In an embodiment, the second capacitor 121_2 may be fixed to the second cavity 110_2 by the second upper fixing pad 124_2 and the second lower fixing pad 125_2. In detail, the second upper fixing pad 124_2 may be arranged between the upper cover 150 and the second capacitor 121_2 and may thus fix the second capacitor 121_2 to the second cavity 110_2. The second lower fixing pad 125_2 may be arranged between the upper case 100U and the second capacitor 121_2 and may thus fix the second capacitor 121_2 to the second cavity 110_2.

In an embodiment, second semiconductor chips may be mounted on the bottom surface of the substrate 140.

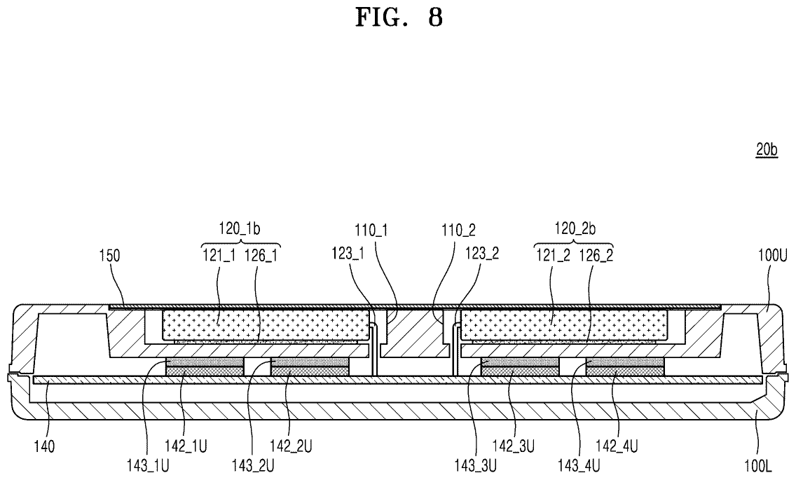

FIG. 8 is a cross-sectional view of a storage device 20b according to an embodiment. FIG. 8 may be described with reference to FIGS. 1 to 4, and redundant descriptions thereof are omitted.

Referring to FIG. 8, the storage device 20b may correspond to the storage device 10a of FIG. 4. The storage device 20b of FIG. 8 may be different from the storage device 10a of FIG. 4 in that a capacitor is fixed to a cavity by an adhesive member. Here, the adhesive member may include epoxy resin, a silicon adhesive, a polyvinyl alcohol (PVA) adhesive, an adhesive film, adhesive tape, a photocurable adhesive, Velcro, glue, or a combination of two or more of these. Besides, any material that is applicable to the bottom surface of a capacitor and capable of fixing the capacitor to the case 100 may be used.

A first capacitor module 120_1b may include the first capacitor 121_1 and a first adhesive member 126_1. The first capacitor 121_1 may be electrically connected to the substrate 140 through the lead 123_1. The lead 123_1 may penetrate the upper case 100U through a hole, which is formed in the upper case 100U, and may be in contact with the substrate 140.

In an embodiment, the first capacitor 121_1 may be fixed to the first cavity 110_1 by the first adhesive member 126_1. In detail, the first adhesive member 126_1 may be arranged between the first capacitor 121_1 and the upper case 100U and may thus fix the first capacitor 121_1 to the first cavity 110_1.

A second capacitor module 120_2b may include the second capacitor 121_2 and a second adhesive member 126_2. The second capacitor 121_2 may be electrically connected to the substrate 140 through the lead 123_2. The lead 123_2 may penetrate the upper case 100U through a hole, which is formed in the upper case 100U, and may be in contact with the substrate 140.

In an embodiment, the second capacitor 121_2 may be fixed to the second cavity 110_2 by the second adhesive member 126_2. In detail, the second adhesive member 126_2 may be arranged between the second capacitor 121_2 and the upper case 100U and may thus fix the second capacitor 121_2 to the second cavity 110_2.

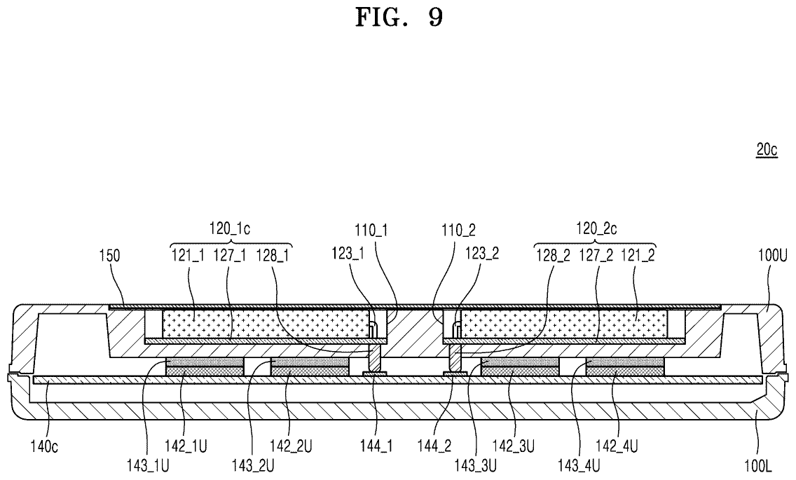

FIG. 9 is a cross-sectional view of a storage device 20c according to an embodiment. FIG. 9 may be described with reference to FIGS. 1 to 4, and redundant descriptions thereof are omitted.

Referring to FIG. 9, the storage device 20c may correspond to the storage device 10a of FIG. 4. The storage device 20c of FIG. 9 may be different from the storage device 10a of FIG. 4 in that a capacitor is fixed to a cavity by a sub substrate and a pogo pin.

A first capacitor module 120_1c may include the first capacitor 121_1, a first sub substrate 127_1, and a first pogo pin 128_1. A substrate 140c may include a first connection pad 144_1 and a second connection pad 144_2.

The first sub substrate 127_1 may be arranged in the first cavity 110_1. The first capacitor 121_1 may be electrically connected to the first sub substrate 127_1 through the lead 123_1. The first sub substrate 127_1 may be connected to the first connection pad 144_1 of the substrate 140c through the first pogo pin 128_1. In other words, the first sub substrate 127_1 may be electrically connected to the substrate 140c through the first pogo pin 128_1. The first pogo pin 128_1 may penetrate the upper case 100U through a hole, which is formed in the upper case 100U, and may be in contact with the first connection pad 144_1.

In an embodiment, the first capacitor 121_1 may be mounted on the first sub substrate 127_1. The first capacitor 121_1 may be fixed to the first sub substrate 127_1 by soldering the lead 123_1 of the first capacitor 121_1 onto the first sub substrate 127_1.

A second capacitor module 120_2c may include the second capacitor 121_2, a second sub substrate 127_2, and a second pogo pin 128_2. The second sub substrate 127_2 may be arranged in the second cavity 110_2. The second capacitor 121_2 may be electrically connected to the second sub substrate 127_2 through the lead 123_2. The second sub substrate 127_2 may be connected to the second connection pad 144_2 of the substrate 140c through the second pogo pin 128_2. In other words, the second sub substrate 127_2 may be electrically connected to the substrate 140c through the second pogo pin 128_2. The second pogo pin 128_2 may penetrate the upper case 100U through a hole, which is formed in the upper case 100U, and may be in contact with the second connection pad 144_2.

In an embodiment, the second capacitor 121_2 may be mounted on the second sub substrate 127_2. The second capacitor 121_2 may be fixed to the second sub substrate 127_2 by soldering the lead 123_2 of the second capacitor 121_2 onto the second sub substrate 127_2.

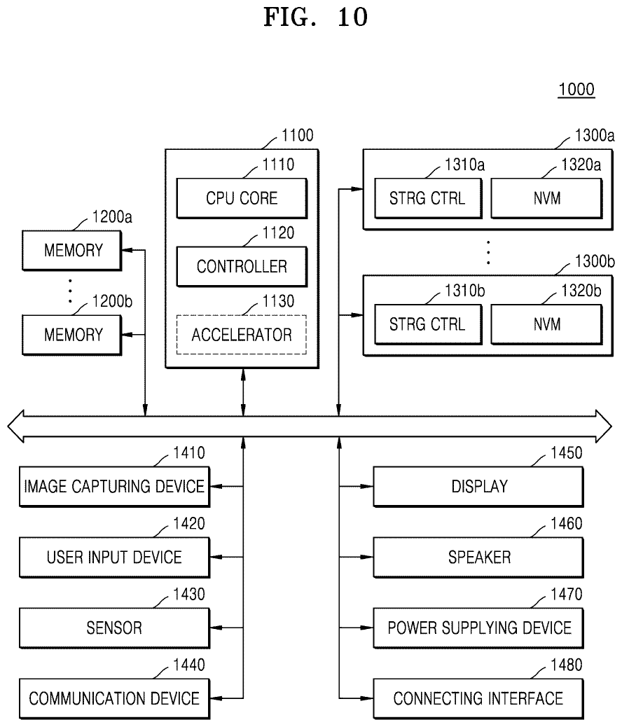

FIG. 10 is a diagram of a system 1000 including a storage device, according to an embodiment.

The system 1000 of FIG. 10 may basically correspond to a mobile system, such as a mobile phone, a smartphone, a tablet personal computer (PC), a wearable device, a healthcare device, or an Internet of things (IoT) device. However, the system 1000 of FIG. 10 is not limited thereto and may correspond to a PC, a laptop computer, a server, a media player, or an automotive device such as a navigation device.

Referring to FIG. 10, the system 1000 may include a main processor 1100, memories 1200a and 1200b, and storage devices 1300a and 1300b and may further include at least one selected from the group consisting of an image capturing device 1410, a user input device 1420, a sensor 1430, a communication device 1440, a display 1450, a speaker 1460, a power supplying device 1470, and a connecting interface 1480. At this time, each of the elements, e.g., the main processor 1100, the memories 1200a and 1200b, the storage devices 1300a and 1300b, the image capturing device 1410, the user input device 1420, the sensor 1430, the communication device 1440, the display 1450, the speaker 1460, the power supplying device 1470, and the connecting interface 1480, of the system 1000 of FIG. 10 may be implemented using the embodiments described above with reference to FIGS. 1 to 9.

The main processor 1100 may generally control the operations of the system 1000, and more particularly, the operations of the other elements of the system 1000. The main processor 1100 may correspond to a general-purpose processor, a dedicated processor, or an application processor.

The main processor 1100 may include at least one central processing unit (CPU) core 1110 and further include a controller 1120, which controls the memories 1200a and 1200b and/or the storage devices 1300a and 1300b. According to an embodiment, the main processor 1100 may further include an accelerator 1130, which is a dedicated circuit for high-speed data operations such as artificial intelligence (AI) data operations. The accelerator 1130 may include a graphics processing unit (GPU), a neural processing unit (NPU), and/or a data processing unit (DPU) and may be implemented in a separate chip physically independent from other elements of the main processor 1100.

The memories 1200a and 1200b may be used as a main memory device of the system 1000 and may include volatile memory, such as SRAM and/or DRAM, or non-volatile memory, such as flash memory, PRAM, and/or RRAM. The memories 1200a and 1200b may be implemented in the same package as the main processor 1100.

The storage devices 1300a and 1300b may include a non-volatile storage device that retains data regardless of power supply and may have a larger capacity than the memories 1200a and 1200b. The storage devices 1300a and 1300b may include storage controllers 1310a and 1310b, respectively, and non-volatile memories 1320a and 1320b, respectively. The non-volatile memory 1320a may store data under control by the storage controller 1310a, and the non-volatile memory 1320b may store data under control by the storage controller 1310b. The non-volatile memories 1320a and 1320b may include flash memory having a two-dimensional (2D) or three-dimensional (3D) vertical NAND (V-NAND) structure or other types of non-volatile memory, such as PRAM and/or RRAM.

The storage devices 1300a and 1300b may be physically separated from the main processor 1100 in the system 1000 or may be implemented in the same package as the main processor 1100. The storage devices 1300a and 1300b may have a form of a solid state drive (SSD) or a memory card and may thus be removably coupled to other elements of the system 1000 through an interface, such as the connecting interface 1480, which will be described below. The storage devices 1300a and 1300b may include a device, to which a protocol, such as a UFS standard, an eMMC standard, or a non-volatile memory express (NVMe) standard, is applied, but are not necessarily limited thereto.

Each of the storage devices 1300a and 1300b may include a plurality of capacitors. When an SPO occurs, a current operation of each of the storage devices 1300a and 1300b may be completed using energy stored in the capacitors so that data to be stored in each of the storage devices 1300a and 1300b may be limited and/or prevented from being lost.

The optical input device 1410 may capture a still image or a moving image and may include a camera, a camcorder, and/or a webcam.

The user input device 1420 may receive various types of data input by a user of the system 1000 and may include a touch pad, a key pad, a keyboard, a mouse, and/or a microphone.

The sensor 1430 may sense various types of physical quantities that may be acquired from outside the system 1000 and may convert sensed physical quantities into electrical signals. The sensor 1430 may include a temperature sensor, a pressure sensor, an illuminance sensor, a position sensor, an acceleration sensor, a biosensor, and/or a gyroscope sensor.

The communication device 1440 may transmit or receive signals to or from other devices outside the system 1000 according to various communication protocols. The communication device 1440 may include an antenna, a transceiver, and/or a modem.

The display 1450 and the speaker 1460 may function as output devices that respectively output visual information and auditory information to the user of the system 1000.

The power supplying device 1470 may appropriately transform power from a battery (not shown) embedded in the system 1000 and/or an external power supply and may supply transformed power to each element of the system 1000.

The connecting interface 1480 may provide a connection between the system 1000 and an external device, which is connected to the system 1000 and may exchange data with the system 1000. The connecting interface 1480 may include various interfaces, such as an ATA interface, a SATA interface, an e-SATA interface, an SCSI, a serial attached SCSI (SAS), a PCI interface, a PCIe interface, an NVMe interface, Institute of Electrical and Electronics Engineers (IEEE) 1394, a USB interface, an SD card interface, a multimedia card (MMC) interface, an embedded MMC (eMMC) interface, a UFS interface, an embedded UFS (eUFS) interface, and a compact flash (CF) card interface.

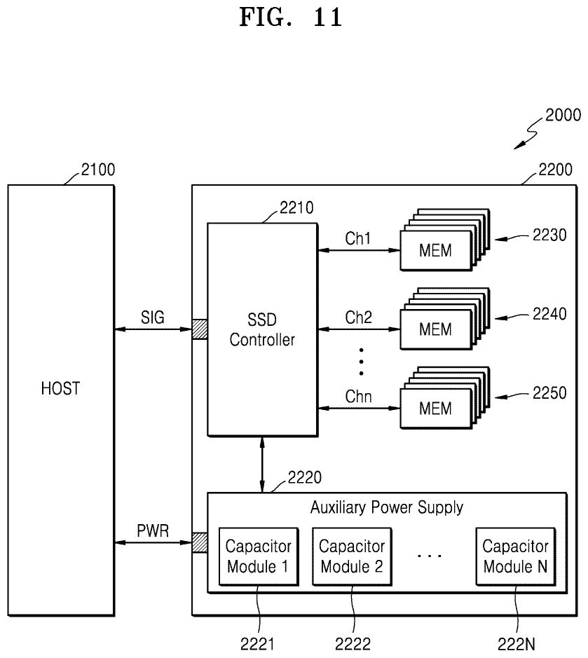

FIG. 11 is a block diagram of an example of applying a storage device to an SSD system, according to embodiments.

Referring to FIG. 11, an SSD system 2000 may include a host 2100 and an SSD 2200. The SSD 2200 may exchange signals SIG with the host 2100 through a signal connector and may receive power PWR through a power connector. The SSD 2200 may include an SSD controller 2210, an auxiliary power supply 2220, and memory devices 2230, 2240, and 2250. Each of the memory devices 2230, 2240, and 2250 may include a vertical stack NAND flash device. The SSD controller 2210 may communicate with the memory devices 2230, 2240, and 2250 through first to n-th channels Ch1 to Chn.

The auxiliary power supply 2220 may be implemented using the embodiments described above with reference to FIGS. 1 to 10. In an embodiment, the auxiliary power supply 2220 may include first to N-th capacitor modules 2221 to 222N. When an SPO occurs and the power PWR supplied from the host 2100 to the SSD 220 is suddenly cut off, the auxiliary power supply 2220 may enable the SSD 2200 to continuously perform a current operation by using capacitance stored in the first to N-th capacitor modules 2221 to 222N. Accordingly, the auxiliary power supply 2220 may limit and/or prevent data to be stored in the SSD 2200 from being lost when an SPO occurs.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While aspects of inventive concepts have been particularly shown and described with reference to embodiments thereof, it will be understood that various changes in form and details may be made therein without departing from the spirit and scope of the following claims.

What is claimed is:

1. A storage device comprising:
a substrate;
a semiconductor chip on the substrate;
a case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction; and
an upper cover on the case, wherein
the capacitor module includes a capacitor in the cavity and the capacitor is configured to supply power to the substrate.

2. The storage device of claim 1, wherein a lead of the capacitor passes through a hole in the case and is in contact with the substrate.

3. The storage device of claim 1, further comprising
a thermal interface material between the semiconductor chip and the case, wherein
the thermal interface material is configured to thermally connect the semiconductor chip to the case.

4. The storage device of claim 3, wherein the plurality of heat dissipation fins are configured to thermally connect the case to the upper cover.

5. The storage device of claim 1, wherein the upper cover overlaps the plurality of heat dissipation fins and the capacitor module in a vertical direction.

6. The storage device of claim 1, wherein the capacitor module further includes a housing configured to accommodate the capacitor and fix the capacitor through a latch.

7. The storage device of claim 1, wherein the capacitor module further includes an adhesive member between the capacitor and a surface of the case defining the cavity.

8. The storage device of claim 1, wherein the capacitor module further includes:
a first fixing pad between the capacitor and the upper cover; and
a second fixing pad between the capacitor and the semiconductor chip.

9. The storage device of claim 1, wherein
the substrate includes a connection pad,
the capacitor module further includes a sub substrate and a pogo pin,
the sub substrate is electrically connected to the capacitor,
the pogo pin is in contact with the connection pad of the substrate, and
the pogo pin is configured to electrically connect the substrate to the sub substrate.

10. A storage device comprising:
a substrate;
a first semiconductor chip on a top surface of the substrate;
a second semiconductor chip on a bottom surface of the substrate;
a case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction; and
an upper cover on the case, wherein
the capacitor module includes a capacitor in the cavity and the capacitor is configured to supply power to the substrate.

11. The storage device of claim 10, wherein a lead of the capacitor passes through a hole in the case and is in contact with the substrate.

12. The storage device of claim 10, further comprising:
a first thermal interface material between the first semiconductor chip and the case, the first thermal interface material being configured to thermally connect the first semiconductor chip to the case; and
a second thermal interface material between the second semiconductor chip and the case, the second thermal interface material being configured to thermally connect the second semiconductor chip to the case.

13. The storage device of claim 12, wherein the plurality of heat dissipation fins are configured to thermally connect the case to the upper cover.

14. The storage device of claim 10, wherein the capacitor module further includes a housing configured to accommodate the capacitor and fix the capacitor through a latch.

15. The storage device of claim 10, wherein
the substrate includes a connection pad, and
the capacitor module further includes a sub substrate and a pogo pin,
the sub substrate is electrically connected to the capacitor,
the pogo pin is in contact with the connection pad of the substrate, and
the pogo pin is configured to electrically connect the substrate to the sub substrate.

16. A storage device comprising:
a substrate;
a semiconductor chip on the substrate;
an upper case including a plurality of heat dissipation fins, a cavity, and a capacitor module configured to be electrically connected to the substrate, the plurality of heat dissipation fins being arranged in a first direction and spaced apart from each other in a second direction that is perpendicular to the first direction;
a lower case configured to be coupled to the upper case; and
an upper cover on the upper case, wherein
the substrate is in the lower case,
the capacitor module includes a capacitor in the cavity, and
the upper case is configured to be coupled to the lower case and allow power to be supplied to the substrate.

17. The storage device of claim 16, wherein a lead of the capacitor passes through a hole in the upper case and is in contact with the substrate.

18. The storage device of claim 16, wherein the capacitor module further includes a housing configured to accommodate the capacitor and fix the capacitor through a latch.

19. The storage device of claim 17, further comprising:
a thermal interface material between the semiconductor chip and the upper case, wherein
the thermal interface material is configured to thermally connect the semiconductor chip to the upper case.

20. The storage device of claim 19, wherein the plurality of heat dissipation fins are configured to thermally connect the upper case to the upper cover.
